(19) United States
(12) Patent Application Publication
(10) Pub. No.: US 2016/0260705 A1
(43) Pub. Date: Sep. 8, 2016

(54) SEMICONDUCTOR DEVICE

(71) Applicant: KABUSHIKI KAISHA TOSHIBA, Tokyo (JP)

(72) Inventor: Takehito IKIMURA, Yokohama Kanagawa (JP)

(21) Appl. No.: 14/828,802

(22) Filed: Aug. 18, 2015

(30) Foreign Application Priority Data
Mar. 3, 2015 (JP) 2015-041089

(51) Int. Cl. H01L 27/06; H01L 23/522; H01L 27/02; H01L 29/10; H01L 29/36; H01L 29/78; H01L 29/06

(52) U.S. Cl. CPC H01L 27/0629; H01L 29/7816; H01L 23/5223; H01L 23/5227; H01L 29/7831; H01L 29/0684; H01L 29/1095; H01L 29/36; H01L 27/0288

(57) ABSTRACT

A semiconductor device according to an embodiment includes a first semiconductor region of a first conductivity type, a second semiconductor region of a second conductivity type in contact with the first semiconductor region, a third semiconductor region of the first conductivity type in contact with the second semiconductor region and spaced from the first semiconductor region, a first insulating film provided between the first semiconductor region and the third semiconductor region on the second semiconductor region, a first electrode provided on the first insulating film, a high-pass filter connected between the first semiconductor region and the third semiconductor region, and a low-pass filter connected between the second semiconductor region and the third semiconductor region.

### CROSS-REFERENCE TO RELATED APPLICATIONS

This application is based upon and claims the benefit of priority from Japanese Patent Application No. 2015-041089, filed on Mar. 3, 2015; the entire contents of which are incorporated herein by reference.

### FIELD

Embodiments described herein relate generally to a semiconductor device.

### BACKGROUND

In a semiconductor device, ESD (Electrostatic Discharge) resistance is requested. However, when ESD is input to a MOSFET (Metal-Oxide-Semiconductor Field-Effect Transistor), an electric current is concentrated on a part of the MOSFET and the MOSFET is easily broken.

### BRIEF DESCRIPTION OF THE DRAWINGS

FIG. 1 is a sectional view showing a semiconductor device according to a first embodiment;

FIG. 2 is a sectional view showing a capacitor of the first embodiment;

FIG. 3 is a plan view showing an inductor of the first embodiment;

FIG. 4 is a schematic sectional view showing an operation of the semiconductor device according to the first embodiment;

FIG. 5 is a schematic sectional view showing a semiconductor device according to a comparative example of the first embodiment;

FIG. 6 is a plan view showing an inductor of a variation of the first embodiment;

FIG. 7 is a schematic sectional view showing a semiconductor device according to a second embodiment;

FIG. 8 is a plan view showing a semiconductor device according to a third embodiment;

FIG. 9 is a schematic sectional view showing the semiconductor device according to the third embodiment, and showing a cross section taken along line A-A′ in FIG. 8;

FIG. 10 is a sectional view showing a semiconductor device according to a fourth embodiment; and

FIGS. 11A and 11B are graphs showing simulation results obtained when an ESD is applied to a semiconductor device with time plotted on the abscissa and source potential and a hole current flowing to a source electrode plotted on the ordinate, FIG. 11A shows a case that the semiconductor device according to the first embodiment is assumed and FIG. 11B shows that the semiconductor device according to the comparative example is assumed.

### DETAILED DESCRIPTION

A semiconductor device according to an embodiment includes a first semiconductor region of a first conductivity type, a second semiconductor region of a second conductivity type in contact with the first semiconductor region, a third semiconductor region of the first conductivity type in contact with the second semiconductor region and spaced from the first semiconductor region, a first insulating film provided between the first semiconductor region and the third semiconductor region on the second semiconductor region, a first electrode provided on the first insulating film, a high-pass filter connected between the first semiconductor region and the third semiconductor region, and a low-pass filter connected between the second semiconductor region and the third semiconductor region.

### First Embodiment

First, a first embodiment is described.

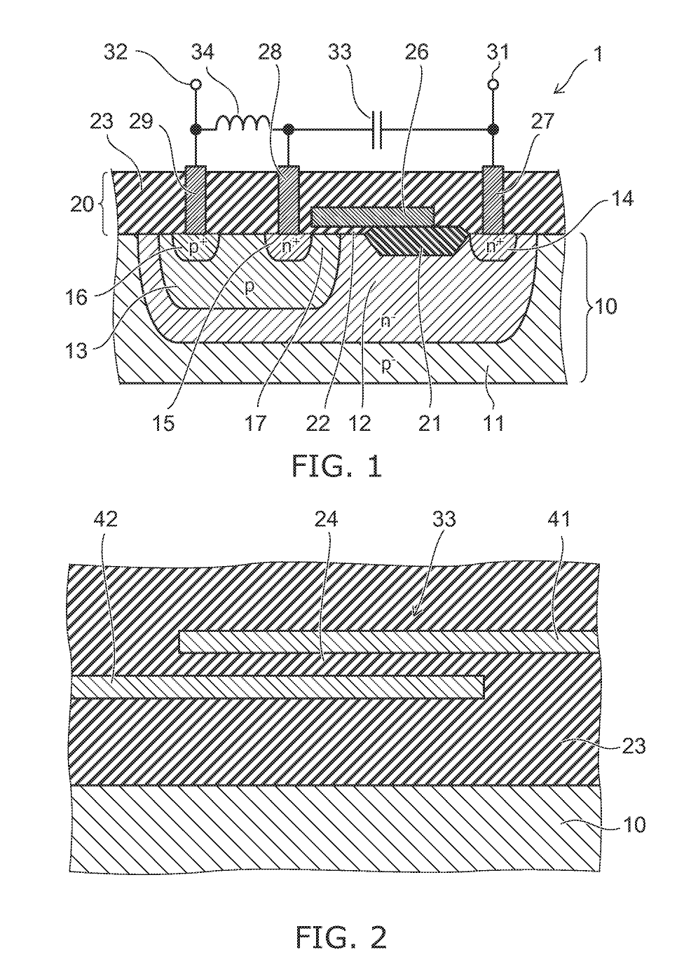

FIG. 1 is a sectional view showing a semiconductor device according to the embodiment.

FIG. 2 is a sectional view showing a capacitor of the embodiment.

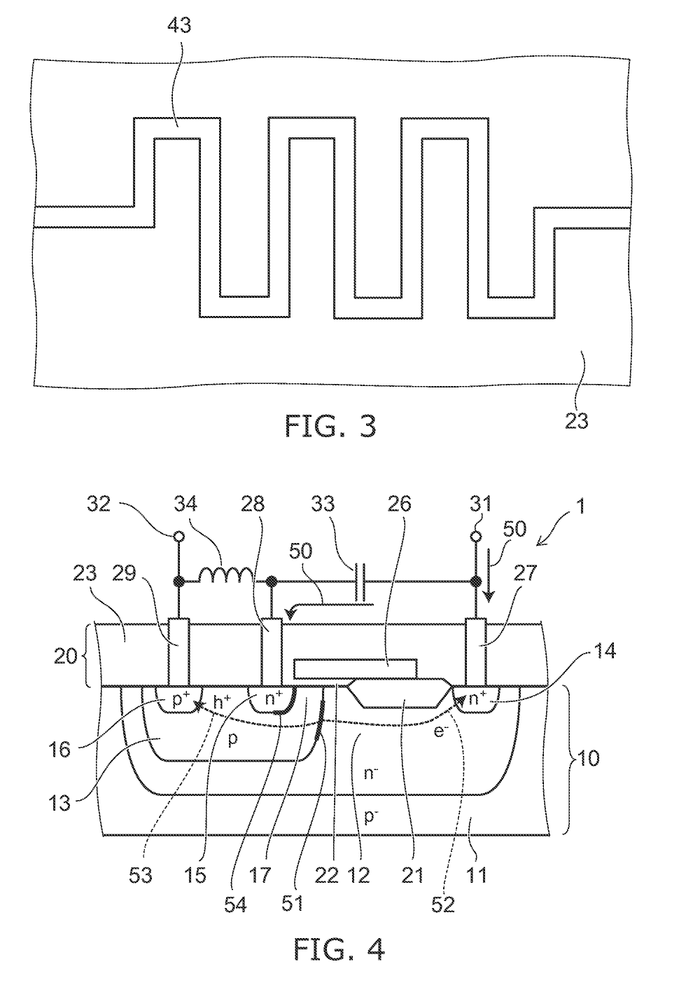

FIG. 3 is a plan view showing an inductor of the embodiment.

As shown in FIG. 1, in a semiconductor device 1 according to the embodiment, an n-channel type LDMOS (Laterally Diffused MOSfet) is formed. Specifically, in the semiconductor device 1, a semiconductor substrate 11, a conductivity type of which is a p⁻-type, is provided. A drift region 12, a conductivity type of which is an n⁻-type, is provided in a part on the semiconductor substrate 11. A drain contact layer 14, a conductivity type of which is an n⁺-type, is provided in a part on the drift region 12. A drain region is formed by the drift region 12 and the drain contact layer 14.

Note that, in the specification, the superscripts “+” and “−” attached to the characters “p” and “n” representing the conductivity types relatively represent carrier concentrations. For example, concerning a region, a conductivity type of which is a p-type, conductivity types are represented as “p⁺-type”, “p-type”, and “p⁻-type” in the descending order of the carrier concentrations. The same applies to an n-type.

The carrier concentration is regarded as effective impurity concentration. The “effective impurity concentration” refers to the concentration of impurities contributing to electric conduction of a semiconductor material. When a certain portion includes both of impurities functioning as a donor and impurities functioning as an accepter, the “effective impurity concentration” refers to concentration excluding offsets of the impurities.

In another part on the drift region 12, a back gate region 13, a conductivity type of which is the p-type, is provided. The back gate region 13 is spaced from the drain contact layer 14 by the drift region 12. In a part on the back gate region 13, a back gate contact layer 16, a conductivity type of which is the p⁺-type, is provided.

In another part on the back gate region 13, a source contact layer 15, a conductivity type of which is the n⁺-type, is provided. The source contact layer 15 configures a source region. The source contact layer 15 is disposed between the drain contact layer 14 and the back gate contact layer 16 and spaced from the back gate contact layer 16 and the drift layer 12 by the back gate region 13.

The semiconductor substrate 11, the drift region 12, the back gate region 13, the drain contact layer 14, the source contact layer 15, and the back gate contact layer 16 are parts of a semiconductor portion 10. The semiconductor portion 10 is formed by a contiguous semiconductor material, for example, single crystal silicon. Therefore, regions and layers adjacent to each other are in contact with each other. For example, the drift region 12 is in contact with the semiconductor substrate 11, the back gate region 13, and the drain contact layer 14. The back gate region 13 is in contact with the source contact layer 15 and the back gate contact layer 16. Note that the semiconductor substrate 11 is not limited to a substrate itself and may be a semiconductor layer formed by doping impurities in the substrate.

A field insulating film 21 is provided between the drain contact layer 14 and the back gate region 13 on the drift region 12. The field insulating film 21 is spaced from the back gate region 13. A lower part of the field insulating film 21 is disposed in the drift region 12. The field insulating film 21 is provided to relax an electric field and improve a breakdown voltage of the LDMOS.

A gate electrode 26 is provided in, on the semiconductor portion 10, a channel portion 17 between the source contact layer 15 and the drift region 12 in the back gate region 13, a portion between the back gate region 13 and the field insulating film 21 in the drift region 12, and a position opposed to a portion on the back gate region 13 side in the field insulating film 21. A gate insulating film 22 is provided between the semiconductor portion 10 and the gate electrode 26. Consequently, a portion on the source contact layer 15 side in the gate electrode 26 is disposed on the gate insulating film 22. A portion on the drain contact layer 14 side in the gate electrode 26 is disposed on the field insulating film 21. The field insulating film 21 is thicker than the gate insulating film 22.

An interlayer insulating film 23 is provided on the semiconductor portion 10 to cover the gate electrode 26. The upper surface of the field insulating film 21 is covered by the gate electrode 26 and the interlayer insulating film 23. The field insulating film 21, the gate insulating film 22, and the interlayer insulating film 23 are parts of an insulating portion 20. The insulating portion 20 is formed of, for example, silicon oxide.

A drain electrode 27, a source electrode 28, and a back gate electrode 29 are provided in the interlayer insulating film 23. The lower end of the drain electrode 27 is ohmic-connected to the drain contact layer 14. The lower end of the source electrode 28 is ohmic-connected to the source contact layer 15. The lower end of the back gate electrode 29 is ohmic-connected to the back gate contact layer 16.

The drain electrode 27 is connected to a drain terminal 31. The back gate electrode 29 is connected to a source terminal 32. A capacitor 33 is connected between the drain electrode 27 and the source electrode 28. An inductor 34 is connected between the source electrode 28 and the back gate electrode 29.

As shown in FIG. 2, the capacitor 33 is, for example, an MIM (Metal-Insulator-Metal) capacitor. In the capacitor 33, an interconnect 41 and an interconnect 42 are opposed to each other via a portion 24 of the interlayer insulating film 23. The interconnect 41 is connected to the drain electrode 27. The interconnect 42 is connected to the source electrode 28. The capacitor 33 is a high-pass filter that interrupts an electric current having a relatively low frequency like an SD signal applied between the drain terminal 31 and the source terminal 32 during a normal operation of the semiconductor device 1 and allows an electric current having a relatively high frequency like ESD to pass. Note that, usually, a waveform of the ESD is a pulse shape. However, the waveform can be regarded as a part of a high-frequency signal. In this case, when time width of a rising edge of the ESD is represented as (¼λ), a cycle of the high-frequency signal corresponding to the ESD can be regarded as λ. For example, the frequency of the SD signal applied between the drain terminal 31 and the source terminal 32 is approximately 1 MHz and the frequency equivalent to the ESD is approximately 50 MHz. The capacitor 33 is, for example, a filter that selectively allows a signal generally having a frequency of 25 MHz or more to pass.

As shown in FIG. 3, the inductor 34 is configured by, for example, a meandering interconnect 43. The inductor 34 is a low-pass filter that allows an electric current having a relatively low frequency like the SD signal to pass and interrupts an electric current having a relatively high frequency like the ESD. The inductor 34 is, for example, a filter that selectively allows a signal generally having a frequency of 2 MHz or less to pass.

The operation of the semiconductor device according to the embodiment is described.

FIG. 4 is a schematic sectional view showing the operation of the semiconductor device according to the embodiment.

As shown in FIG. 4, during the normal operation of the semiconductor device 1, drain potential of positive polarity is applied to the drain terminal 31 and source potential of negative polarity, for example, ground potential is applied to the source terminal 32. At this point, the drain potential is applied to the drain electrode 27. The source potential is applied to the back gate electrode 29. The source potential is also applied to the source electrode 28 via the inductor 34. On the other hand, the capacitor 33 is interposed between the drain electrode 27 and the source electrode 28. Therefore, the drain electrode 27 and the source electrode 28 are not short-circuited. When the potential of the gate electrode 26 is smaller than a threshold, a depletion layer expands starting from a pn interface 51 between an n⁻-type drift region 12 and the p-type back gate region 13. An electric current does not flow between the drain terminal 31 and the source terminal 32.

In this state, when an ESD current 50 of positive polarity is input to the drain terminal 31, the ESD current 50 flows into the drift region 12 via the drain electrode 27 and the drain contact layer 14. The potential of the drift region 12 rises. When a potential difference between the drift region 12 and the back gate region 13 exceeds a breakdown voltage, avalanche breakdown occurs on a pn interface 51 and a hole-electron pair is generated. A generated electron current 52 is absorbed by the drain electrode 27. A generated hole current 53 is absorbed by the back gate electrode 29.

At this point, a part of the ESD current 50 input to the drain terminal 31 flows into the source electrode 28 via the capacitor 33. Therefore, the potential of the source contact layer 15 rises. Consequently, a pn interface 54 between a p-type back gate region 13 and the n⁺-type source contact layer 15 changes to a reverse bias state. It is possible to prevent the hole current 53 from flowing into the source contact layer 15. Consequently, it is possible to prevent an electron current from flowing from the source contact layer 15 to the back gate region 13 because the hole current 53 flows into the source contact layer 15. As a result, a parasitic npn bipolar transistor composed of the n− -type drift region 12, the p-type back gate region 13, and the n+-type source contact layer 15 does not conduct. A snap-back phenomenon does not occur. Therefore, it is possible to prevent a situation in which the parasitic npn bipolar transistor conducts because of the ESD current 50, a large current flows into a conducting portion, and the semiconductor device 1 is broken.

Note that the inductor 34 functioning as the low-pass filter does not allow the ESD current 50 to flow. Therefore, the ESD current 50 does not flow into the back gate contact layer 16 via the back gate electrode 29. Therefore, the hole current 53 is not hindered from flowing to the back gate contact layer 16. When an ESD current of negative polarity is input to the drain terminal 31, the pn interface 51 changes to a forward bias state and allows the ESD current to directly flow. Therefore, a problem less easily occurs.

Effects of the embodiment are described.

As described above, in the semiconductor device 1, the capacitor 33 functioning as the high-pass filter is connected between the drain electrode 27 and the source electrode 28. Therefore, when the ESD current 50 of positive polarity is input to the drain terminal 31, a part of the ESD current 50 flows into the source electrode 28 and increases the potential of the source contact layer 15. Therefore, even if the avalanche breakdown is caused by the ESD current 50 flowing into the drift region 12 via the drain electrode 27, a hole current caused by the avalanche breakdown is suppressed from flowing into the source contact layer 15. Conduction of the parasitic npn bipolar transistor is suppressed. Therefore, the snap-back current less easily flows. As a result, a local voltage drop due to the snap-back phenomenon does not occur. Therefore, local concentration of the ESD current does not occur and the semiconductor device 1 is less easily broken down. In this way, according to the embodiment, it is possible to realize a semiconductor device having high ESD resistance.

### Comparative Example of the First Embodiment

A comparative example of the first embodiment is described.

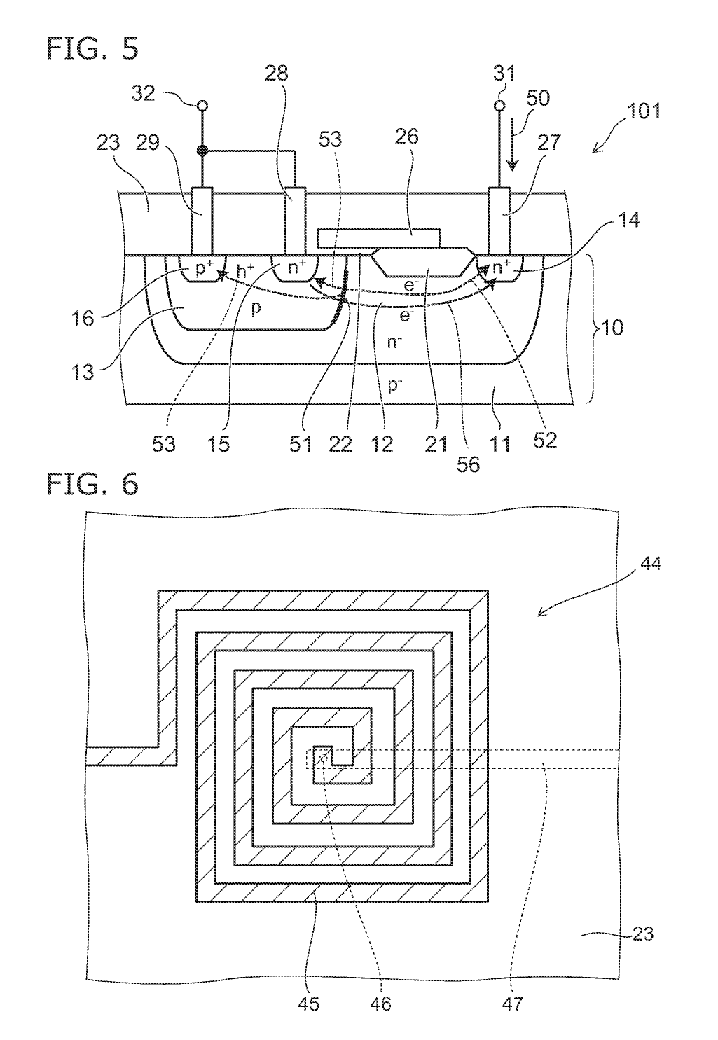

FIG. 5 is a schematic sectional view showing a semiconductor device according to the comparative example.

As shown in FIG. 5, in a semiconductor device 101 according to the comparative example, the capacitor 33 (see FIG. 1) and the inductor 34 (see FIG. 1) are not provided. The source electrode 28 is short-circuited to the back gate electrode 29.

In the semiconductor device 101 according to the comparative example, when the ESD current 50 of positive polarity is input to the drain terminal 31, the ESD current 50 does not flow into the source electrode 28. The potential of the source contact layer 15 does not rise. Therefore, when the avalanche breakdown is caused by the ESD current 50 flowing into the drift region 12 via the drain electrode 27 and the electron current 52 and the hole current 53 are generated from the pn interface 51, the hole current 53 flows into the back gate region 13. When the potential of the back gate contact layer 16 rises, a part of the hole current 53 flows into the source contact layer 15.

According to the inflow of the hole current 53, an electron current 56 flows into the back gate region 13 from the source contact layer 15. The electron current 56 is absorbed by the drain electrode 27 via the drift region 12 and the drain contact layer 14. That is, a collector current flows into a parasitic npn bipolar transistor in which the n⁻-type drift region 12 is a collector, the p-type back gate region 13 is a base, and the n⁺-type source contact layer 15 is an emitter. The electron current 56 causes larger avalanche breakdown on the pn interface 51. When this phenomenon occurs, the breakdown voltage of the pn interface 51 excessively drops and a so-called snap-back phenomenon occurs. Once the snap-back phenomenon occurs in a certain portion, a voltage applied to the other portions is reduced and an ESD current does not flow. Therefore, an electric current concentratedly flows to a portion where the snap-back phenomenon occurs first. The semiconductor device 101 is broken down. In this way, the semiconductor device 101 according to the comparative example has ESD resistance lower than the ESD resistance of the semiconductor device 1 according to the first embodiment.

### Variation of the First Embodiment

A variation of the first embodiment is described.

FIG. 6 is a plan view showing an inductor of the variation.

As shown in FIG. 6, in the variation, an inductor 44 is connected between the source electrode 28 (see FIG. 1) and the back gate electrode 29 (see FIG. 1). In the inductor 44, a spiral interconnect 45, a via 46 connected to an end of the interconnect 45 located in the center of the spiral, and an interconnect 47 connected to the via 46 are provided. The interconnect 47 is disposed lower than the interconnect 45. Note that, for convenience of illustration, the interconnect 45 is hatched. The interconnect 45 is connected to the back gate electrode 29. The interconnect 47 is connected to the source electrode 28. Necessary inductance can also be obtained by the inductor 44.

Components, operations, and effects other than those described in the variation above are the same as the those of the first embodiment described above.

### Second Embodiment

A second embodiment is described.

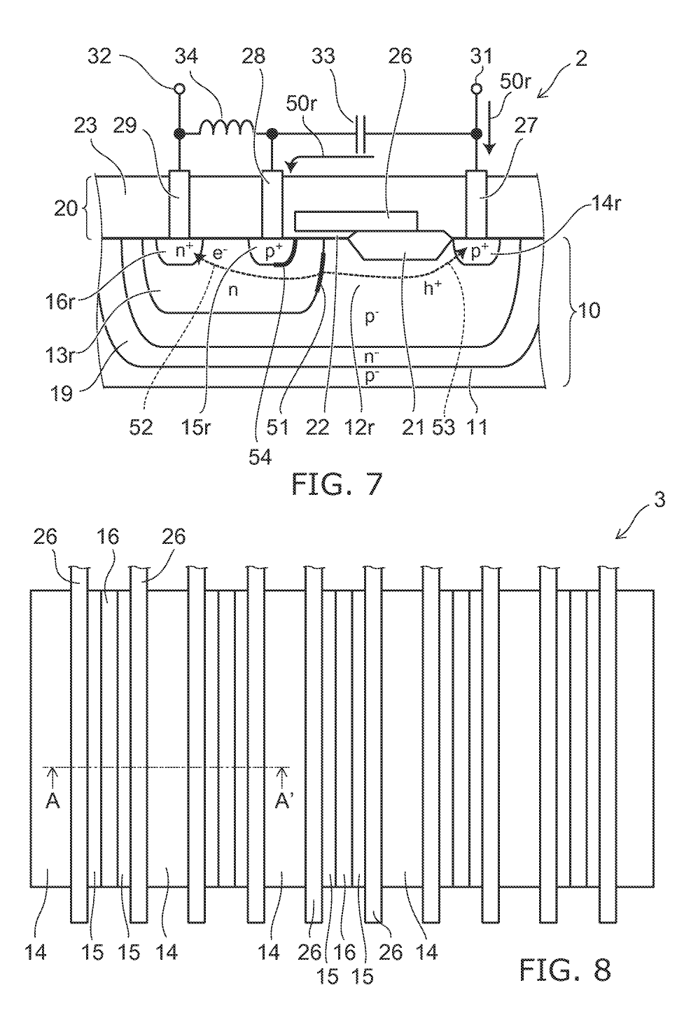

FIG. 7 is a schematic sectional view showing a semiconductor device according to the embodiment.

As shown in FIG. 7, in a semiconductor device 2 according to the embodiment, an n-type well 19 is formed on the semiconductor substrate 11, a conductivity type of which is the p⁻-type. A p-channel type LDMOS is formed on the well 19. In the p-channel type LDMOS, a conductivity type of semiconductor regions is opposite compared with the n-channel type LDMOS in the first embodiment.

Specifically, the n-type well 19 is formed on the p⁻-type semiconductor substrate 11. A p⁻-type drift region 12r is provided on the well 19. An n-type back gate region 13r and a p⁺-type drain contact layer 14r are provided spaced from each other on the p⁻-type drift region 12r. A p⁺-type source contact layer 15r and an n⁺-type back gate contact layer 16r are provided spaced apart from each other on the back gate region 13r. A field insulating film 21 is provided between the back gate region 13r and the drain contact layer 14r. Components other than the components described above in the semiconductor device 2 are the same as those of the semiconductor device 1 (see FIG. 1) according to the first embodiment.

The operation of the semiconductor device according to the embodiment is described.

In the semiconductor device 2, drain potential of negative polarity, for example, ground potential is applied to the drain terminal 31. A source potential of positive polarity is applied to the source terminal 32. In the embodiment, an ESD current 50r of negative polarity is input to the drain terminal 31. Note that this situation is equivalent to the situation in which an ESD current of positive polarity is input to the source terminal 32 while the drain potential is fixed to the ground potential.

The ESD current 50r of negative polarity input to the drain terminal 31 flows into the drift region 12r via the drain electrode 27 and the drain contact layer 14r and reduces the potential of the drift region 12r. When a potential difference between the p⁻-type drift region 12r and the n-type back gate region 13r exceeds a breakdown voltage, avalanche breakdown occurs on the pn interface 51 and a hole-electron pair is generated. The generated electron current 52 is absorbed by the back gate electrode 29. The generated hole current 53 is absorbed by the drain electrode 27.

At this point, a part of the ESD current 50r input to the drain terminal 31 flows into the source electrode 28 via the capacitor 33. Therefore, the potential of the source contact layer 15r drops. Consequently, the pn interface 54 between the n-type back gate region 13r and the p⁺-type source contact layer 15r changes to a reverse bias state. It is possible to prevent the electron current 52 from flowing into the source contact layer 15r. Consequently, it is possible to prevent a hole current from flowing from the source contact layer 15r to the back gate region 13r because the electron current 52 flows into the source contact layer 15r. As a result, it is possible to suppress conduction of a parasitic pnp bipolar transistor composed of the p⁻-type drift region 12r, the n-type back gate region 13r, and the p⁺-type source contact layer 15r. A snap-back phenomenon less easily occurs. Therefore, it is possible to suppress a situation in which the parasitic pnp bipolar transistor conducts because of the ESD current 50r, a large current locally flows, and the semiconductor device 2 is broken.

Effects of the embodiment are described.

In the embodiment, as in the first embodiment, the capacitor 33 functioning as the high-pass filter is connected between the drain electrode 27 and the source electrode 28. Therefore, when the ESD current 50r of negative polarity is input to the drain terminal 31, a part of the ESD current 50r flows into the source electrode 28 and reduces the potential of the source contact layer 15r. Therefore, an electron current caused by the avalanche breakdown is suppressed from flowing into the source contact layer 15r. The parasitic pnp bipolar transistor less easily conduct. Therefore, the snap-back current less easily flows. In this way, according to the embodiment, it is also possible to realize a semiconductor device having high ESD resistance.

### Third Embodiment

A third embodiment is described.

FIG. 8 is a plan view showing a semiconductor device according to the embodiment.

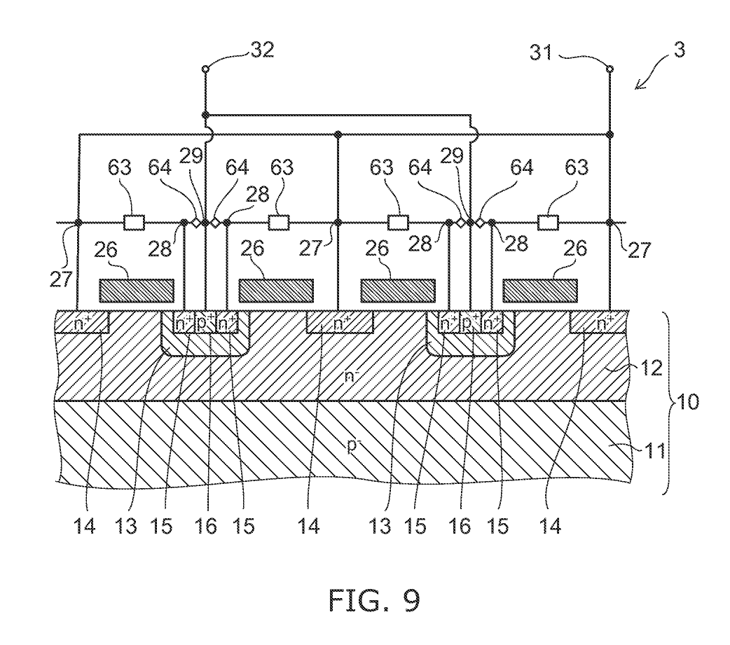

FIG. 9 is a schematic sectional view showing the semiconductor device according to the embodiment. FIG. 9 shows a cross section taken along line A-A′ in FIG. 8.

Note that, for convenience of illustration, in FIGS. 8 and 9, the gate insulating film 22 and the interlayer insulating film 23 are omitted. The drain electrode 27, the source electrode 28, and the back gate electrode 29 are omitted in FIG. 8 and shown as nodes in FIG. 9.

As shown in FIGS. 8 and 9, in a semiconductor device 3 according to the embodiment, a finger-type MOSFET is formed. That is, the n⁻-type drift layer 12 is provided on the p⁻-type semiconductor substrate 11. On the drift layer 12, belt-like n⁺-type drain contact layers 14 and belt-like p-type back gate regions 13 are arrayed alternately and spaced from each other. In each of the back gate regions 13, one belt-like p⁺-type back gate contact layer 16 and two belt-like n⁺-type source contact layers 15 are provided. The source contact layers 15 are disposed on both the sides of the back gate contact layer 16. Note that, in an example shown in FIGS. 8 and 9, the field insulating film 21 (see FIG. 1) is not provided. However, as shown in FIG. 1, the field insulating film 21 may be provided.

In the semiconductor device 3, as in the semiconductor device 1 (see FIG. 1), a high-pass filter 63 is connected between the drain electrode 27 and the source electrode 28. A low-pass filter 64 is connected between the source electrode 28 and the back gate electrode 29. The high-pass filter 63 may be a capacitor. The low-pass filter 64 may be an inductor.

In the embodiment, as in the first embodiment, when an ESD current of positive polarity is input to the drift terminal 31, it is possible to suppress a snap-back phenomenon by increasing the potential of the source contact layer 15 via the high-pass filter 63. As a result, it is possible to feed the ESD current to entire belt-like transistor regions. It is possible to avoid breakage of the semiconductor device 3 due to current concentration.

Components, operations, and effects other than those described above in the embodiment are the same as those of the first embodiment described above.

### Fourth Embodiment

A fourth embodiment is described.

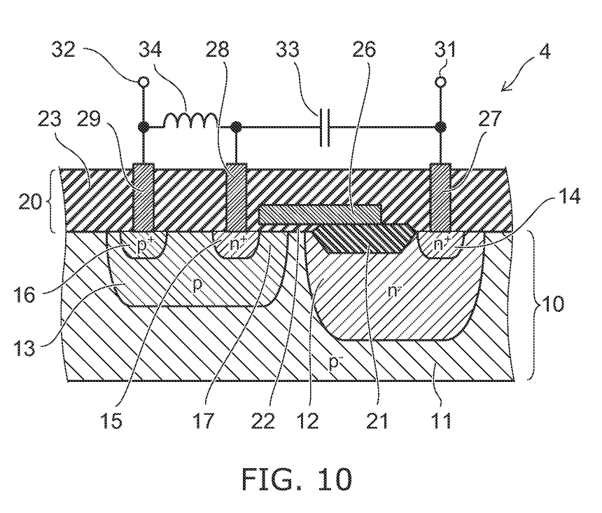

FIG. 10 is a schematic sectional view showing the semiconductor device according to the embodiment.

As shown in FIG. 10, in a semiconductor device 4 according to the embodiment, the back gate region 13 is provided in a part on the semiconductor substrate 11, and the n⁻-type drift layer 12 is provided in a part on the semiconductor substrate 11.

Components, operations, and effects other than those described above in the embodiment are the same as those of the first embodiment described above.

### EXPERIMENT EXAMPLE

An experiment example indicating the effects of the first embodiment described above is described.

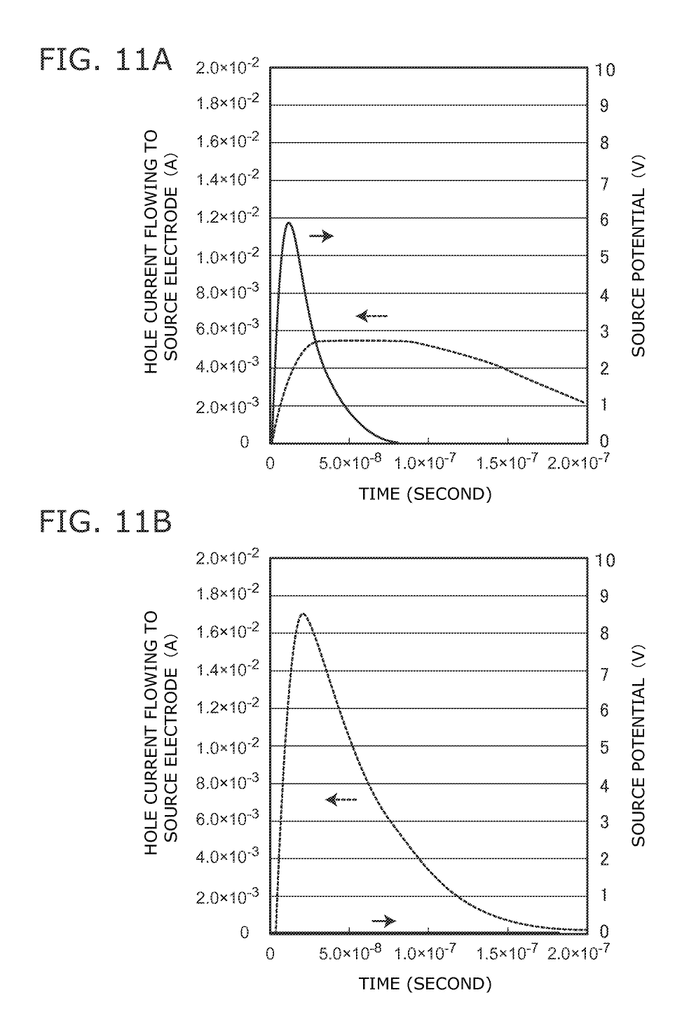

FIGS. 11A and 11B are graphs showing simulation results obtained when an ESD is applied to a semiconductor device with time plotted on the abscissa and source potential (a solid line) and a hole current (a dotted line) flowing to a source electrode plotted on the ordinate, FIG. 11A shows a case that the semiconductor device according to the first embodiment is assumed and FIG. 11B shows that the semiconductor device according to the comparative example is assumed.

In the experiment example, a simulation was performed assuming an n-channel-type LDMOS having gate width of 800 μm. In the semiconductor device according to the first embodiment (see FIG. 1), a capacitor having a capacity of 0.5 pF was connected as a high-pass filter between the drain electrode and the source electrode and an inductor having inductance of 50 nH was connected as a low-pass filter between the source electrode and the back gate electrode. On the other hand, in the semiconductor device according to the comparative example (see FIG. 5), a high-pass filter was not connected between the drain electrode and the source electrode and the source electrode and the back gate electrode were short-circuited. An ESD current of +2000 V conforming to a HBM (Human Body Model) of JEDEC was applied to the drain electrode with reference to the source electrode and the back gate electrode.

As shown in FIG. 11A, in the semiconductor device according to the first embodiment, the source potential rose to approximately 6 V. The hole current flowing to the source electrode was able to be suppressed to approximately 5.5×10⁻³ A (ampere).

On the other hand, as shown in FIG. 11B, in the semiconductor device according to the comparative example, the source potential did not rise. The hole current flowing to the source electrode was approximately 1.7×10⁻² A.

In this way, according to the first embodiment, compared with the comparative example, the hole current flowing to the source electrode was able to be suppressed to approximately one third. As described above, it is possible to prevent the snap-back phenomenon by suppressing the hole current flowing to the source electrode.

According to the embodiments described above, it is possible to realize a semiconductor device having high ESD resistance.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor device comprising:
a first semiconductor region of a first conductivity type;
a second semiconductor region of a second conductivity type in contact with the first semiconductor region;
a third semiconductor region of the first conductivity type in contact with the second semiconductor region and spaced from the first semiconductor region;
a first insulating film provided between the first semiconductor region and the third semiconductor region on the second semiconductor region;
a first electrode provided on the first insulating film;
a high-pass filter connected between the first semiconductor region and the third semiconductor region; and
a low-pass filter connected between the second semiconductor region and the third semiconductor region.

2. The device according to claim 1, wherein the high-pass filter includes a capacitor.

3. The device according to claim 1, wherein the low-pass filter includes an inductor.

4. The device according to claim 1, further comprising:
a second electrode connected to the first semiconductor region;
a third electrode connected to the second semiconductor region; and
a fourth electrode connected to the third semiconductor region, wherein
the second semiconductor region is disposed in a part on the first semiconductor region,
the third semiconductor region is disposed in a part on the second semiconductor region,
the high-pass filter is connected between the second electrode and the fourth electrode, and
the low-pass filter is connected between the third electrode and the fourth electrode.

5. The device according to claim 4, further comprising a second insulating film, wherein
the first semiconductor region includes:
a drift region in contact with the second semiconductor region; and
a first contact layer in contact with the second electrode and having carrier concentration higher than carrier concentration of the drift region,
the second semiconductor region includes:
a back gate region in contact with the first semiconductor region and the third semiconductor region; and
a second contact layer in contact with the third electrode and having carrier concentration higher than carrier concentration of the back gate region, and
the second insulating film is disposed between the first contact layer and the second semiconductor region.

6. The device according to claim 5, wherein the second insulating film is thicker than the first insulating film.

7. The device according to claim 4, wherein the first conductivity type is an n-type, the second conductivity type is a p-type, the second electrode is a drain electrode, the third electrode is a back gate electrode, and the fourth electrode is a source electrode.

8. The device according to claim 4, wherein the first conductivity type is a p-type, the second conductivity type is an n-type, the second electrode is a drain electrode, the third electrode is a back gate electrode, and the fourth electrode is a source electrode.

9. A semiconductor device comprising:
a first semiconductor region of a first conductivity type;
a second semiconductor region of a second conductivity type in contact with the first semiconductor region;
a third semiconductor region of the first conductivity type in contact with the second semiconductor region and spaced from the first semiconductor region;
a first insulating film provided between the first semiconductor region and the third semiconductor region on the second semiconductor region;
a first electrode provided on the first insulating film;
a capacitor connected between the first semiconductor region and the third semiconductor region; and
a inductor connected between the second semiconductor region and the third semiconductor region.

10. The device according to claim 9, wherein the capacitor and the inductor are configured by interconnects.

11. The device according to claim 9, wherein the capacitor is an MIM capacitor.

12. A semiconductor device comprising:
a first semiconductor region;
a second semiconductor region of a first conductivity type provided on the first semiconductor region;
a third semiconductor region of the first conductivity type provided on the second semiconductor region;
a fourth semiconductor region of a second conductivity type provided on the first semiconductor region;
a fifth semiconductor region of the second conductivity type provided on the fourth semiconductor region;
a sixth semiconductor region of the first conductivity type provided on the fourth semiconductor region;
a first insulating film provided between the second semiconductor region and the sixth semiconductor region on the fourth semiconductor region;
a first electrode provided on the first insulating film;
a high-pass filter connected between the third semiconductor region and the sixth semiconductor region; and
a low-pass filter connected between the fifth semiconductor region and the sixth semiconductor region.

13. The device according to claim 12, wherein the high-pass filter includes a capacitor.

14. The device according to claim 12, wherein the low-pass filter includes an inductor.

15. The device according to claim 12, further comprising:
a second electrode connected to the third semiconductor region;
a third electrode connected to the fifth semiconductor region; and
a fourth electrode connected to the sixth semiconductor region, wherein
the high-pass filter is connected between the second electrode and the fourth electrode, and
the low-pass filter is connected between the third electrode and the fourth electrode.

16. The device according to claim 12, further comprising a second insulating film provided on the second semiconductor region, the second insulating film being thicker than the first insulating film.

17. The device according to claim 12, wherein
carrier concentration of the third semiconductor region is higher than carrier concentration of the second semiconductor region, and
carrier concentration of the fifth semiconductor region is higher than carrier concentration of the fourth semiconductor region.

18. The device according to claim 12, wherein the fifth semiconductor region is in contact with the sixth semiconductor region.

19. The device according to claim 13, wherein the capacitor is configured by interconnects.

20. The device according to claim 14, wherein the inductor is configured by interconnects.
